(19) United States
(12) Patent Application Publication
(10) Pub. No.: US 2008/0283876 A1
(43) Pub. Date: Nov. 20, 2008

(54) Noise detection circuit

(75) Inventor: Masaaki Souda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/149,501

(22) Filed: May 2, 2008

(30) Foreign Application Priority Data
May 14, 2007 (JP) 2007-128041

(51) Int. Cl. H01L 29/00

(52) U.S. Cl. 257/254; 257/E29.001

(57) ABSTRACT

Noise occurring in a circuit is more accurately detected. A low-pass filter (11) is connected to a power supply line for a power supply terminal (VDD), and noise in the power supply line is removed to generate and output a referential voltage (V0). A high-pass filter (12) is connected to a power supply line, and a noise signal in the power supply line is passed with the referential voltage (V0) as a reference. A high-pass filter (13) is connected to a ground line for a ground terminal (GND), and a noise signal in the ground line is passed based on the referential voltage (V0) as a reference. A reference voltage generation circuit (14) generates and outputs a reference voltage (Vref) based on the referential voltage (V0) as a reference. Comparison circuits (CMP1 and CMP2) respectively compare output voltage of the high-pass filters (12 and 13) and the reference voltage (Vref). A noise determining circuit (15) changes the reference voltage (Vref) to obtain a comparison result at the same time for the comparison circuits (CMP1 and CMP2).

### REFERENCE TO RELATED APPLICATION

This application is based upon and claims the benefit of the priority of Japanese patent application No. 2007-128041, filed on May 14, 2007, the disclosure of which is incorporated herein in its entirety by reference thereto.

### FIELD OF THE INVENTION

This invention relates to a noise detection circuit, and in particular to a noise detection circuit for detecting noise generated in a power supply inside a semiconductor chip.

### BACKGROUND OF THE INVENTION

In recent years, power supply noise environment in LSI chips has deteriorated due to increasing speeds, increased precision, and increased density of LSI chips, and trouble due to the power supply noise has been increasing. As a result, measurement of power supply noise actually generated inside an LSI chip is becoming important. A power supply noise measurement device that measures this type of power supply noise is described for example in Patent Document 1.

FIG. 6 is a block diagram showing main parts of the power supply noise measurement device derived from Patent Document 1. In FIG. 6, a noise component is removed from a power supply line on which noise is superimposed, using a low-pass filter (LPF) 101, and a signal from which the noise component has been removed is outputted to a voltage dividing circuit 102 as a reference voltage supply V0. Furthermore, a signal from the power supply line is passed through a high-pass filter (HPF) 103, and a divided voltage outputted by the voltage dividing circuit 102 is added to this by an adder 104 to generate a first signal. On the other hand, reference voltage indicating data undergoes a DA conversion by a DA converter 105 and a second signal is generated. A comparator 106 outputs a result of comparing voltage of the first signal and voltage of the second signal, and a counter 107 counts cases in which the voltage of the first signal is greater than or equal to the voltage of the second signal. A sample and hold circuit 108 samples and holds a count value just before resetting of the counter 107. Since the power supply noise measurement device configured in this way is provided with the high-pass filter 103, an error does not occur in noise voltage measured by direct current fluctuations of a power supply signal, and it is possible to accurately evaluate the noise voltage.

Moreover, as related technology, Patent Document 2 describes a noise detection device which prevents a malfunction due to noise of an electronic device from occurring.

### [Patent Document 1]

JP Patent Kokai Publication No. JP-P2005-249408 (Pages 6 to 10, FIG. 4).

### [Patent Document 2]

JP Patent Kokai Publication No. JP-P2004-32170

### SUMMARY OF THE DISCLOSURE

The entire disclosures of Patent Documents 1 and 2 are incorporated herein by reference thereto. The following analyses are given by the present inventor.

However, in a circuit of Patent Document 1, a path for measuring power supply noise from a power supply line through a high-pass filter 103 is provided, but there is no path for detecting noise of a ground line. Inside a semiconductor chip, ground noise is propagated between blocks through a silicon substrate. In cases in which ground noise is present, there is a risk that a referential voltage created through a low-pass filter 101 will fluctuate. Thus, when only measuring noise on a power supply side, it is not possible to accurately measure noise occurring in a circuit inside the chip. In this way, in the circuit of Patent Document 1, since it is not possible to measure ground noise, attempts to more accurately comprehend the noise occurring in the circuit are not necessarily sufficient.

According to a first aspect of the present invention there is provided a noise detection circuit comprising at least first and second power supply terminals, and being arranged in a semiconductor device including first and second power supply lines connected respectively to the first and the second power supply terminals. The noise detection circuit includes a low-pass filter which is connected to the first power supply line and which removes noise in the first power supply line to generate and output a referential voltage; a first high-pass filter which is connected to the first power supply line and which passes a noise signal in the first power supply line based on the referential voltage as a reference; and a second high-pass filter which is connected to the second power supply line and which passes a noise signal in the second power supply line based on the referential voltage as a reference A reference voltage generation circuit which generates and outputs a reference voltage based on the referential voltage as a reference. A first comparison circuit compares output voltage of the first high-pass filter and the reference voltage. A second comparison circuit compares output voltage of the second high-pass filter and the reference voltage.

According to a second aspect, the noise detection circuit further comprises a noise determining circuit which changes the reference voltage to obtain a comparison result at an identical time for the first and the second comparison circuits.

According to a third aspect, the first high-pass filter may comprise:
a first capacitive element, one end of which is connected to the first power supply line, an other end of which is connected to a first comparison input terminal of the first comparison circuit,
a first resistance element, one end of which is connected to output of the low-pass filter, an other end of which is connected to the other end of the first capacitive element, and
a first current supply circuit which supplies a current to the other end of the first resistance element,
so that output voltage of the first high-pass filter is outputted from the other end of the first capacitive element.

The second high-pass filter may comprise:
a second capacitive element, one end of which is connected to the second power supply line, an other end of which is connected to a first comparison input terminal of the second comparison circuit,
a second resistance element, one end of which is connected to output of the low-pass filter, an other end of which is connected to an other end of the second capacitive element, and
a second current supply circuit which supplies a current to the other end of the second resistance element,
so that output voltage of the second high-pass filter is outputted from the other end of the second capacitive element.

The reference voltage generation circuit may comprise:
a variable resistance circuit, one end of which is connected to output of the low-pass filter, an other end of which is connected to second comparison input terminals of the first and the second comparison circuits, and
a third current supply circuit which supplies current to the other end of the variable resistance circuit,
so that the reference voltage is outputted from the other end of the variable resistance circuit.

According to a fourth aspect, the variable resistance circuit may comprise a plurality of resistance elements whose connection mode is changed according to a reference voltage control signal for changing the reference voltage.

According to a fifth aspect, each of the first, the second, and the third current supply circuits may comprise a MOS transistor which is given a gate voltage based on a reference current generated between the referential voltage and voltage of the second power supply line.

According to a sixth aspect, the low-pass filter may comprise a resistance element and a capacitive element.

According to a seventh aspect, there is provided a semiconductor device comprising the noise detection circuit according to any one of foregoing aspects.

The meritorious effects of the present invention are summarized as follows.

According to the present invention, not only noise detection of the first power supply line, but also noise detection of the second power supply line is possible, and it is possible to more accurately comprehend (i.e. detect) noise occurring in a circuit. The reason for this is that it is possible to extract noise superimposed on the second power supply line by providing the second high-pass filter connected to the second power supply line.

### BRIEF DESCRIPTION OF THE DRAWINGS

FIG. 1 is a block diagram showing a configuration of a noise detection circuit according to an exemplary of the present invention.

FIG. 2 is a diagram showing a waveform example of various parts of the noise detection circuit.

FIG. 3 is a circuit diagram of main parts of the noise detection circuit according to the exemplary of the present invention.

FIG. 4 is a circuit diagram showing an example of a variable resistance circuit.

FIG. 5 is a circuit diagram showing an example of a current supply circuit.

FIG. 6 is a block diagram showing main parts of a conventional power supply noise measurement device.

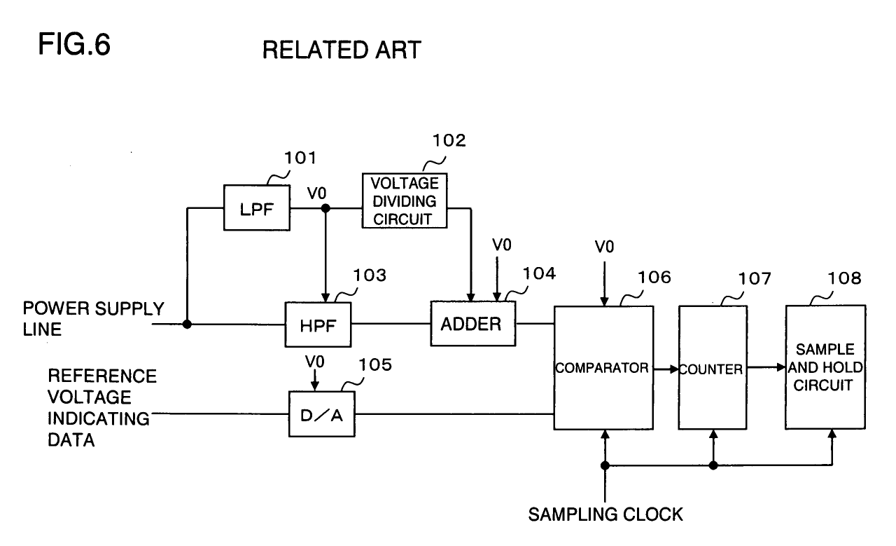

### PREFERRED MODES OF THE INVENTION

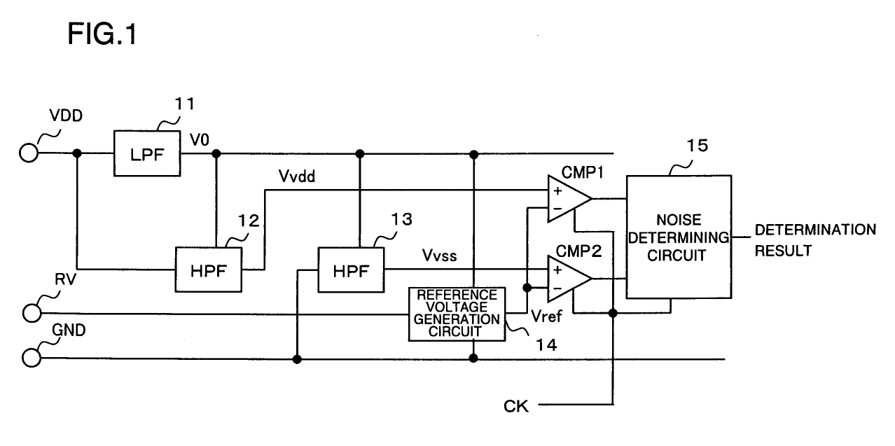

A noise detection circuit according to an exemplary embodiment of the present invention is provided with a first power supply terminal (VDD in FIG. 1) and a second power supply terminal (GND is FIG. 1), and is arranged in a semiconductor device including first and second power supply lines connected respectively to the first and the second power supply terminals. The noise detection circuit includes a low-pass filter (11 in FIG. 1) which is connected to the first power supply line and removes noise in the first power supply line to generate and output a referential voltage (V0 in FIG. 1); a first high-pass filter (12 in FIG. 1) which is connected to the first power supply line and which passes a noise signal contained in the first power supply line based on the referential voltage (V0 in FIG. 1) as a reference; a second high-pass filter (13 in FIG. 1) which is connected to the second power supply line and which passes a noise signal in the second power supply line based on the referential voltage as a reference; a reference voltage generation circuit (14 in FIG. 1) which generates and outputs a reference voltage (Vref) based on the referential voltage as a reference; a first comparison circuit (CMP1 in FIG. 1) which compares output voltage of the first high-pass filter and the reference voltage (Vref); and a second comparison circuit (CMP2 in FIG. 1) which compares output voltage (Vss) of the second high-pass filter and the reference voltage.

Furthermore, it is preferable to provide a noise determining circuit (15 in FIG. 1) which changes the reference voltage to obtain a comparison result at the same time for the first and the second comparison circuits.

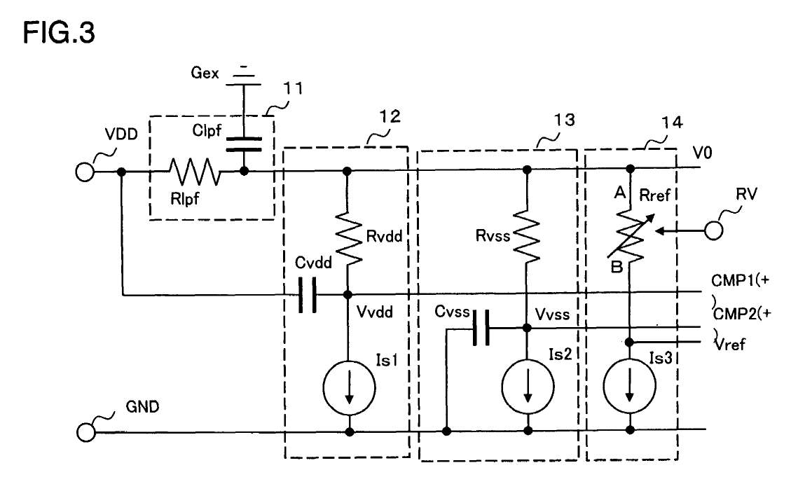

Here, the first high-pass filter may be provided with a first capacitive element (Cvdd in FIG. 3), one end of which is connected to the first power supply line, the other end of which is connected to a first comparison input terminal of the first comparison circuit, a first resistance element (Rvdd in FIG. 3), one end of which is connected to output of the low-pass filter, the other end of which is connected to the other end of the first capacitive element, and a first current supply circuit (Is1 in FIG. 3) which supplies a current to the other end of the first resistance element, so that output voltage of the first high-pass filter is outputted from the other end of the first capacitive element; the second high-pass filter may be provided with a second capacitive element (Cvss in FIG. 3), one end of which is connected to the second power supply line, the other end of which is connected to a first comparison input terminal of the second comparison circuit, a second resistance element (Rvss in FIG. 3), one end of which is connected to output of the low-pass filter, the other end of which is connected to the other end of the second capacitive element, and a second current supply circuit (Is2 in FIG. 3) which supplies a current to the other end of the second resistance element, so that output voltage of the second high-pass filter is outputted from the other end of the second capacitive element; and the reference voltage generation circuit may be provided with a variable resistance circuit (Rref in FIG. 3), one end of which is connected to output of the low-pass filter, the other end of which is connected to a second comparison input terminal of the first and the second comparison circuits, and a third current supply circuit (Is3 in FIG. 3) which supplies current to the other end of the variable resistance circuit, so that the reference voltage (Vref in FIG. 3) is outputted from the other end of the variable resistance circuit.

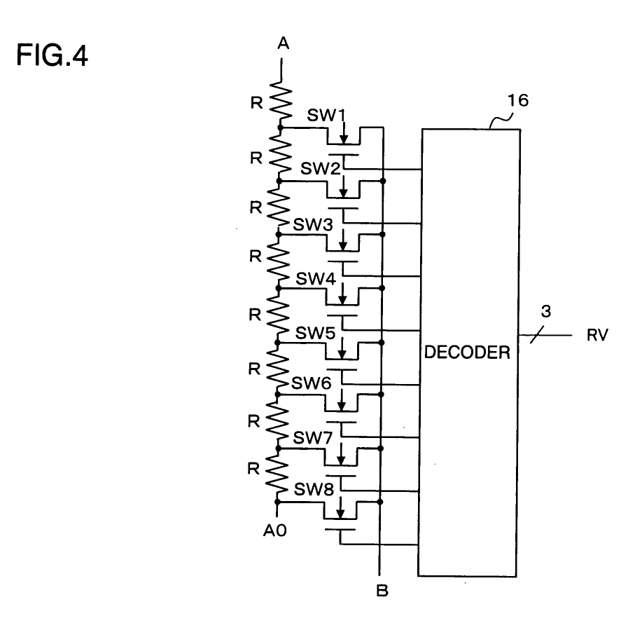

Furthermore, the variable resistance circuit may be configured from a plurality of resistance elements (R in FIG. 4) whose connection mode is changed according to a reference voltage control signal for changing the reference voltage.

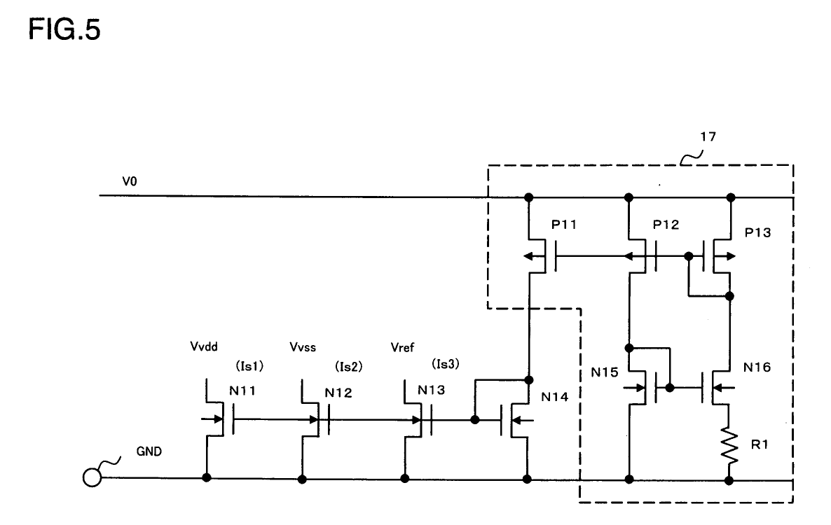

Moreover, each of the first, the second, and the third current supply circuits may be configured as MOS transistors (N11, N12, and N13 in FIG. 5) which are given a gate voltage based on a reference current generated between the referential voltage and the voltage of the second power supply line.

Furthermore, the low-pass filter may be formed by the resistance element (Rlpf of FIG. 3) and the capacitive element (Clpf of FIG. 3).

The semiconductor device preferably includes the above type of noise detection circuit.

Below, a more specific explanation is given concerning the noise detection circuit, making reference to the drawings. FIG. 1 is a block diagram showing a configuration of the noise detection circuit according to an exemplary embodiment of the present invention. In FIG. 1, the noise detection circuit is provided with a low-pass filter (LPF) 11, high-pass filters (HPF) 12 and 13, a reference voltage generation circuit 14, a comparators CMP1 and CMP2, a noise determining circuit 15, a power supply terminal VDD, a ground terminal GND, and a reference voltage setting terminal RV.

In the low-pass filter 11, an input terminal is connected to a power supply line for a power supply terminal VDD for which noise is to be measured, and a referential voltage V0, in which noise in the power supply line is removed, is outputted to the high-pass filters 12 and 13, and the reference voltage generation circuit 14. Output of the low-pass filter 11 is used as a referential voltage for the high-pass filters 12 and 13 and the reference voltage generation circuit 14.

An input terminal of the high-pass filter 12 is connected to a power supply line for a power supply terminal VDD for which noise is to be measured. The high-pass filter 12 removes a DC component of the voltage of the power supply line and outputs a noise component only. Furthermore, in the high-pass filter 12, based on the referential voltage V0 created in the low-pass filter 11 and potential of the ground terminal GND, an output center voltage of the high-pass filter 12 is created. That is, the output voltage Vvdd of the high-pass filter 12 is a voltage in which the voltage of the noise component of the power supply line for the power supply terminal VDD is superimposed on the output center voltage. Furthermore, in FIG. 1, connections for explaining functions of the high-pass filter 12 are represented, but connections with the ground terminal GND are not shown.

An input terminal of the high-pass filter 13 is connected to a ground line for the ground terminal GND for which noise is to be measured. The high-pass filter 13 removes a DC component of the ground line, and outputs a noise component only. Furthermore, similarly to the high-pass filter 12, based on the referential voltage V0 and potential of the ground terminal GND, an output center voltage is created. That is, an output voltage Vvss of the high-pass filter 13 is a voltage in which the voltage of the noise component of the ground line for the ground terminal GND is superimposed on the output center voltage. Moreover, the output center voltage of the high-pass filter 13 is made equal to the output center voltage of the high-pass filter 12.

The reference voltage generation circuit 14, based on the referential voltage V0 and potential of the ground terminal GND, outputs a reference voltage Vref necessary for measuring noise amplitude. In order that the reference voltage Vref has a voltage variation range that is sufficient for noise amplitude measurement with the output center voltage of the high-pass filters 12 and 13 as center, output of the reference voltage generation circuit 14 is made variable by a reference voltage setting terminal RV (see FIG. 3).

The comparator CMP1 compares the output voltage Vvdd and the reference voltage Vref by timing of a sampling clock CK, and outputs a comparison result to the noise determining circuit 15. Furthermore, the comparator CMP2 compares the output voltage Vvss and the reference voltage Vref by timing of the sampling clock CK, and outputs a comparison result to the noise determining circuit 15.

The comparison results of the comparators CMP1 and CMP2 are inputted to the noise determining circuit 15 and made to correspond with timing of the sampling clock CK, to obtain a comparison result at the same time for the output voltage Vvdd and the output voltage Vvss. Configuration of the noise determining circuit 15 is not particularly limited, and, for example, two sets of a sample and hold circuit and a counter similar to conventional cases may be embedded. In cases in which the output voltage Vvdd and the output voltage Vvss are each greater than or equal to the reference voltage Vref, the respective counters add to the respective counts, and the respective sample and hold circuits may be configured to sample and hold respective count values just before the counters are reset. In such cases, the respective sample values held represent the output voltage Vvdd and the output voltage Vvss at a sampling point in time.

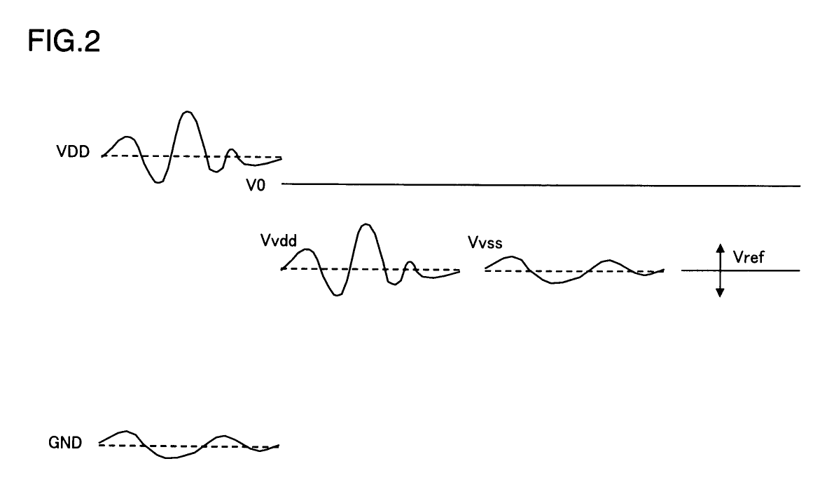

Next, using FIG. 2, an explanation is given concerning operation of the noise detection circuit. A signal (represented by VDD in FIG. 2) of the power supply line in which noise is superimposed and a signal (represented by GND in FIG. 2) of the ground line are inputted to the noise detection circuit. First, the low-pass filter 11 generates the referential voltage V0 in which noise from a signal of the power supply line is removed. Based on this referential voltage V0, the high-pass filter 12 outputs the noise component (represented by Vvdd in FIG. 2) of the power supply line with the output center voltage as center. Furthermore, the high-pass filter 13 outputs the noise component (represented by Vvss in FIG. 2) of the ground line with the output center voltage as center. Moreover, the reference voltage generation circuit 14 outputs the (quiet) reference voltage Vref in which there is very little noise. By changing a signal given to the reference voltage setting terminal RV, the value of the reference voltage Vref changes. When measuring the noise, the value of the reference voltage Vref is changed, and it is possible to measure amplitude of the noise where output of the comparator changes.

According to the above type of noise detection circuit, since not only noise detection on a power supply side but also noise detection on a ground side is possible, detection of true noise sensed by the circuit is possible. The reason for this is that it is possible to extract noise superimposed on the ground side by providing the high-pass filter 13 at a ground side terminal. Furthermore, in order to curtail effects on a measurement node as much as possible, even if ground potential fluctuates due to noise on the ground side, the circuit itself is configured so that there is high impedance from ground.

Furthermore, according to the above type of noise detection circuit, by providing the power supply itself for the noise detection circuit from the noise measurement circuit, a dedicated power supply for the noise detection circuit is not necessary. The reason for this is because a quiet power supply necessary for measurement is self-produced, through the low-pass filter from the power supply of the noise measurement circuit. According to this configuration, since there is no necessity to make a dedicated power supply plane for the noise detection circuit, creating of a package or a measurement board becomes easy.

### EXAMPLE 1

Next, an explanation is given concerning a specific circuit example of the noise detection circuit. FIG. 3 is a circuit diagram of main parts of the noise detection circuit according to the exemplary embodiment of the present invention.

A low-pass filter 11 is composed of a resistance element Rlpf and a capacitive element Clpf. A cutoff frequency of the low-pass filter 11 is set lower than a frequency in which noise is included, and values of the resistance element Rlpf and the capacitive element Clpf are decided so that a noise component is sufficiently removed. Furthermore, ground to which the capacitive element Clpf is connected is preferably static ground without noise. Therefore, a terminal on a side not connected to the low-pass filter output terminal side of the capacitive element Clpf is preferably connected to ground Gex, such as a board or the like, close to static ground. Here, in cases in which the noise detection circuit is embedded in the semiconductor device, the capacitive element Clpf may be external to the semiconductor device.

The high-pass filter 12 is provided with the capacitive element Cvdd, one end of which is connected to the power supply terminal VDD, the other end of which is connected to a first comparison (non-inverted) input terminal (+) of the comparison circuit CMP1; the resistance element Rvdd, one end of which is connected to output of the low-pass filter 11, the other end of which is connected to the other end of the capacitive element Cvdd; and the current supply circuit Is1 which supplies current to the other end of the resistance element Rvdd. The capacitive element Cvdd and the resistance element Rvdd form a high-pass filter. A cutoff frequency due to the capacitive element Cvdd and the resistance element Rvdd is set lower than a noise frequency component on the power supply side that is to be measured. The current supply circuit Is1 has an impedance that is sufficiently high with respect to the ground terminal GND. The center voltage of output of the high-pass filter 12 is decided based on the current value of the current supply circuit Is1 times the value of the resistance element Rvdd.

The high-pass filter 13 is provided with the capacitive element Cvss, one end of which is connected to a ground terminal GND, the other end of which is connected to a first comparison input terminal (+, non-inverted) of the comparison circuit CMP2; the resistance element Rvss, one end of which is connected to output of the low-pass filter 11, the other end of which is connected to the other end of the capacitive element Cvss; and a current supply circuit Is2 which supplies current to the other end of the resistance element Rvss. The capacitive element Cvss and the resistance element Rvss form a high-pass filter. A cutoff frequency according to the capacitive element Cvss and the resistance element Rvss is set lower than a noise frequency component on the ground side that is to be measured. The current supply circuit Is2 has an impedance that is sufficiently high with respect to the ground terminal GND. The center voltage of output of the high-pass filter 13 is decided based on the current value of the current supply circuit Is2 times the value of the resistance element Rvss.

In the high-pass filters 12 and 13, if the current values of the current supply circuits Is1 and Is2 and the resistance values of the resistance elements Rvdd and Rvss are set appropriately, noise components included in the power supply line and ground line are outputted, both having an equal center voltage.

The reference voltage generation circuit 14 is provided with a variable resistance circuit Rref, one end of which is connected to output of the low-pass filter 11, the other end of which is connected to second comparison input terminals (−, inverted) of the comparators CMP1 and CMP2, and a current supply circuit Is3 which supplies current to the other end of the variable resistance circuit Rref, to output the reference voltage Vref from the other end of the variable resistance circuit Rref. The current supply circuit Is3 has an impedance that is sufficiently high with respect to the ground terminal GND. A value of the variable resistance circuit Rref is not limited but preferably the current value of the current supply circuit Is3 is the same value as the current supply circuits Is1 and Is2 inside the high-pass filters 12 and 13, and it is preferable that when a center value of the resistance value of the variable resistance circuit Rref is made equal to the resistance values of the resistance elements Rvdd and Rvss within the high-pass filters 12 and 13, the set center becomes equal to the center voltage of the high-pass filters 12 and 13.

FIG. 4 is a circuit diagram showing an example of the variable resistance circuit Rref. In the variable resistance circuit Rref, for example, 8 resistance elements R are connected in series between nodes A to A0, and respective switch elements SW1 to SW8 are provided between 2 resistance elements thereof, and node A0 and node B. Furthermore, a decoding circuit 16 is provided which decodes a 3-bit signal received from the reference voltage setting terminal RV into 8 bits, and decoded output of each is connected to control terminals of the switch elements SW1 to SW8. The variable resistance circuit Rref configured in this way can vary the resistance values between the nodes A to B, to become R, 2R, 3R, . . . 8R (here the resistance value of a resistance element R is represented as R), in accordance with the 3-bit signal received from the reference voltage setting terminal RV.

FIG. 5 is a circuit diagram showing an example of the current supply circuits Is1, Is2, and Is3. In FIG. 5, a reference current generation circuit 17 which has, as a power supply, the ground line and output of the low-pass filter 11 that outputs the referential voltage V0, and N-channel transistors N11, N12, N13, and N14, are provided.

The reference current generation circuit 17 is provided with N-channel transistors N15, and N16, P-channel transistors P11, P12, and P13, and a resistance element R1. The N-channel transistor N16 whose source is connected to the ground line via the resistance element R1 forms a current mirror circuit with the diode-connected N-channel transistor N15. Drains of the diode-connected P-channel transistor P13 and the P-channel transistor P12, which forms a current mirror circuit with the P-channel transistor P13, are respectively connected to drains of the N-channel transistors N16 and N15. Furthermore, a drain of the P-channel transistor P11 that forms a current mirror circuit with the P-channel transistor P13 is connected to a drain of the diode-connected N-channel transistor N14.

The N-channel transistor N14 and the N-channel transistor N11 form a current mirror circuit, the N-channel transistor N14 and the N-channel transistor N12 form a current mirror circuit, and the N-channel transistor N14 and the N-channel transistor N13 form a current mirror circuit.

In the above type of circuit, the reference current generation circuit 17 supplies current as a reference to the N-channel transistors N11, N12, and N13 that respectively form the current circuits Is1, Is2, and Is3, from a drain of the P-channel transistor P11. In such cases, in order that output current does not vary even if noise is superimposed on the ground line side, it is important that each transistor that forms the reference current generation circuit 17 operates in a sufficiently saturated region. Furthermore, in order that noise of the ground line side is not propagated to a drain side, the size of the N-channel transistors N11, N12, and N13, is selected so that impedance between drain and source is sufficiently high.

The present invention has been explained according to the abovementioned exemplary embodiment and examples, but the present invention is not limited to the abovementioned exemplary embodiment and examples, and clearly includes various types of modifications and adjustments that can be envisaged by a person skilled in the art, within the scope of each of the claims of the present invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A noise detection circuit comprising:
at least first and second power supply terminals;
a noise detection circuit arranged in a semiconductor device that includes first and second power supply lines connected respectively to the first and the second power supply terminals;
a low-pass filter which is connected to the first power supply line and which removes noise in the first power supply line to generate and output a referential voltage;
a first high-pass filter which is connected to the first power supply line and which passes a noise signal in the first power supply line based on the referential voltage as a reference;
a second high-pass filter which is connected to the second power supply line and which passes a noise signal in the second power supply line based on the referential voltage as a reference;
a reference voltage generation circuit which generates and outputs a reference voltage based on the referential voltage as a reference;
a first comparison circuit which compares output voltage of the first high-pass filter and said reference voltage; and
a second comparison circuit which compares output voltage of the second high-pass filter and said reference voltage.

2. The noise detection circuit according to claim 1, further comprising a noise determining circuit which changes said reference voltage to obtain a comparison result at an identical time for the first and the second comparison circuits.

3. The noise detection circuit according to claim 1, wherein
said first high-pass filter comprises:
a first capacitive element, one end of which is connected to the first power supply line, an other end of which is connected to a first comparison input terminal of the first comparison circuit,
a first resistance element, one end of which is connected to output of the low-pass filter, an other end of which is connected to the other end of the first capacitive element, and
a first current supply circuit which supplies a current to the other end of the first resistance element,
so that output voltage of the first high-pass filter is outputted from the other end of the first capacitive element;
said second high-pass filter comprises:
a second capacitive element, one end of which is connected to the second power supply line, an other end of which is connected to a first comparison input terminal of the second comparison circuit,
a second resistance element, one end of which is connected to output of the low-pass filter, an other end of which is connected to an other end of the second capacitive element, and
a second current supply circuit which supplies a current to the other end of the second resistance element,
so that output voltage of the second high-pass filter is outputted from the other end of the second capacitive element; and
said reference voltage generation circuit comprises:
a variable resistance circuit, one end of which is connected to output of said low-pass filter, an other end of which is connected to second comparison input terminals of the first and the second comparison circuits, and
a third current supply circuit which supplies current to the other end of the variable resistance circuit,
so that the reference voltage is outputted from the other end of the variable resistance circuit.

4. The noise detection circuit according to claim 3, wherein the variable resistance circuit comprises a plurality of resistance elements whose connection mode is changed according to a reference voltage control signal for changing the reference voltage.

5. The noise detection circuit according to claim 3, wherein each of the first, the second, and the third current supply circuits comprises a MOS transistor which is given a gate voltage based on a reference current generated between the referential voltage and voltage of the second power supply line.

6. The noise detection circuit according to claim 1 wherein said low-pass filter comprises a resistance element and a capacitive element.

7. A semiconductor device comprising the noise detection circuit according to claim 1.

8. A noise detection circuit comprising:
at least first and second power supply terminals;
a noise detection circuit arranged in a semiconductor device that includes first and second power supply lines connected respectively to the first and the second power supply terminals;
a low-pass filter which is connected to the first power supply line and which removes noise in the first power supply line to generate and output a referential voltage;
a first high-pass filter which is connected to the first power supply line and which passes a noise signal in the first power supply line based on the referential voltage as a reference;
a second high-pass filter which is connected to the second power supply line and which passes a noise signal in the second power supply line based on the referential voltage as a reference;
a reference voltage generation circuit which generates and outputs a reference voltage based on the referential voltage as a reference;
a first comparison circuit which compares output voltage of the first high-pass filter and said reference voltage;
a second comparison circuit which compares output voltage of the second high-pass filter and said reference voltage; and
a noise determining circuit which changes said reference voltage to obtain a comparison result at an identical time for the first and the second comparison circuits.

9. The noise detection circuit according to claim 8, wherein
said first high-pass filter comprises:
a first capacitive element, one end of which is connected to the first power supply line, an other end of which is connected to a first comparison input terminal of the first comparison circuit,
a first resistance element, one end of which is connected to output of the low-pass filter, an other end of which is connected to the other end of the first capacitive element, and
a first current supply circuit which supplies a current to the other end of the first resistance element,
so that output voltage of the first high-pass filter is outputted from the other end of the first capacitive element;
said second high-pass filter comprises:
a second capacitive element, one end of which is connected to the second power supply line, an other end of which is connected to a first comparison input terminal of the second comparison circuit,
a second resistance element, one end of which is connected to output of the low-pass filter, an other end of which is connected to an other end of the second capacitive element, and
a second current supply circuit which supplies a current to the other end of the second resistance element,
so that output voltage of the second high-pass filter is outputted from the other end of the second capacitive element; and
said reference voltage generation circuit comprises:
a variable resistance circuit, one end of which is connected to output of said low-pass filter, an other end of which is connected to second comparison input terminals of the first and the second comparison circuits, and
a third current supply circuit which supplies current to the other end of the variable resistance circuit,
so that the reference voltage is outputted from the other end of the variable resistance circuit.

10. The noise detection circuit according to claim 9, wherein the variable resistance circuit comprises a plurality of resistance elements whose connection mode is changed according to a reference voltage control signal for changing the reference voltage.

11. The noise detection circuit according to claim 9, wherein each of the first, the second, and the third current supply circuits comprises a MOS transistor which is given a gate voltage based on a reference current generated between the referential voltage and voltage of the second power supply line.

12. The noise detection circuit according to claim 8 wherein said low-pass filter comprises a resistance element and a capacitive element.

13. A semiconductor device comprising the noise detection circuit according to claim 8.
